(19) United States
(12) Patent Application Publication
(10) Pub. No.: US 2006/0228817 A1
(43) Pub. Date: Oct. 12, 2006

(54) Dispensable capacitor manufacturing process

(76) Inventor: Ho-Ching Yang, Ping Chen City (TW)

Correspondence Address: LEONG C LEI, PMB # 1008, 1867 YGNACIO VALLEY ROAD, WALNUT CREEK, CA, 94598, US

(21) Appl. No.: 11/100,449

(22) Filed: Apr. 7, 2005

(51) Int. Cl. H01L 21/20; H01L 21/66; G01R 31/26

(52) U.S. Cl. 438/17; 438/381

(57) ABSTRACT

A dispensable capacitor manufacturing process allowing easier process, capacity correction facilitating, and reduced production cost essentially involves dispensing conductive epoxy between two soldering points on a PCB, use of laser to cut on the surface of solidified epoxy spaced grooves in different forms, heated dielectric material then permeated, insulation layer coated on surface after solidification, test and correction to constitute capacitor.

### BACKGROUND OF THE INVENTION

(a) Technical Field of the Invention

The present invention is related to a manufacturing process of dispensable capacitor, and more particularly, to a capacitor manufacturing process that is simplified, capacity correction facilitating, and allowing reduced production cost.

(b) Description of the Prior Art

As illustrated in FIGS. 1, and 2 of the accompanying drawings, the manufacturing process of the ceramic capacitor is generally available in the market and usually involves dispensing an electrode 11 on multiple ceramic green sheets 1 with one end of the electrode 11 staying closely to the lateral side of the ceramic green sheet while another end of the electrode 11 keeping a proper spacing from another lateral side of the ceramic green sheet 1 before stacking up those multiple ceramic green sheets 1 with the spaced sides between any two layered sheets 1 facing away from each other. Both lateral sides of the deck are then respectively provided each with a soldering end 12 to constitute a capacitor 100. However, this manufacturing process of the prior is found with the following flaws:
1. Complicated process, increased production cost, and higher percentage of nonconformity.
2. Capacity error prevents correction for the capacitor 100 since capacity of the electrode dispensed is preset.
3. Enormous manufacturing facilities required consumes too much space, slower return of investment on the machinery, thus less competitive.

### SUMMARY OF TH NVENTION

The primary purpose of the present invention is to provide a dispensable capacitor manufacturing process that is simplified, allowing correction of capacity and reduced production cost. In the present invention, conductive epoxy is dispensed between two soldering points on a PCB to omit the soldering process as needed in the prior art. The conductive epoxy dispensed is heated up and solidified before the laser cut on the surface of the epoxy spaced grooves, then dielectric material is coated and solidified to be followed with test, correction and repeated testing. An insulation protection layer is coated on the top of the conductive epoxy and dielectric material to improve impact and thermal durability while promoting the binding property of the PCB. Furthermore, two layers of conductive epoxy may be dispensed for increased capacity.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings, identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective view of a ceramic capacitor of the prior art.

FIG. 2 is a sectional view of a cut-away from the ceramic capacitor of the prior art.

FIG. 3 is a process flow chart of the present invention.

FIG. 4 is a schematic view showing a dispensable conductive epoxy of the present invention.

FIG. 5 is a sectional view showing the dispensable conductive epoxy of the present invention.

FIG. 6 is a schematic view showing a pattern of the laser cut on the conductive epoxy of the present invention.

FIG. 7 is a schematic view showing another pattern of the laser cut on the conductive epoxy of the present invention.

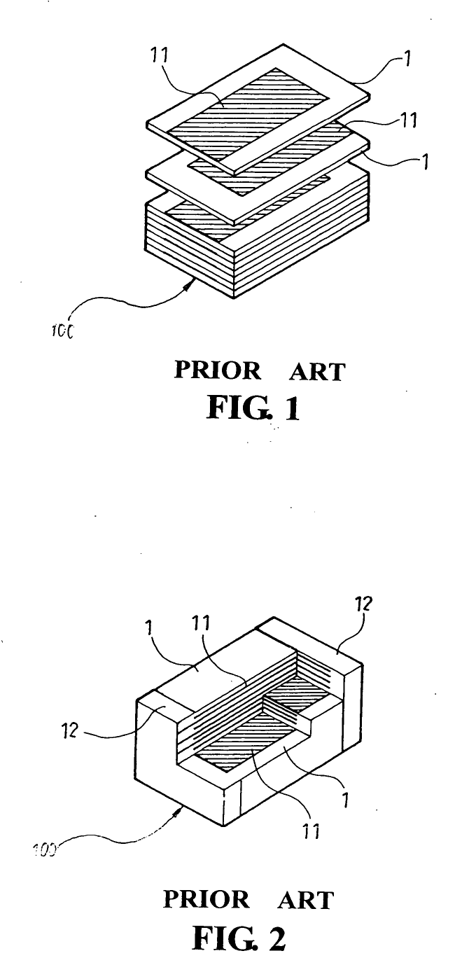

### DETAILED DESCRIPTION OF THE PREFERRED EMBODIMENTS

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

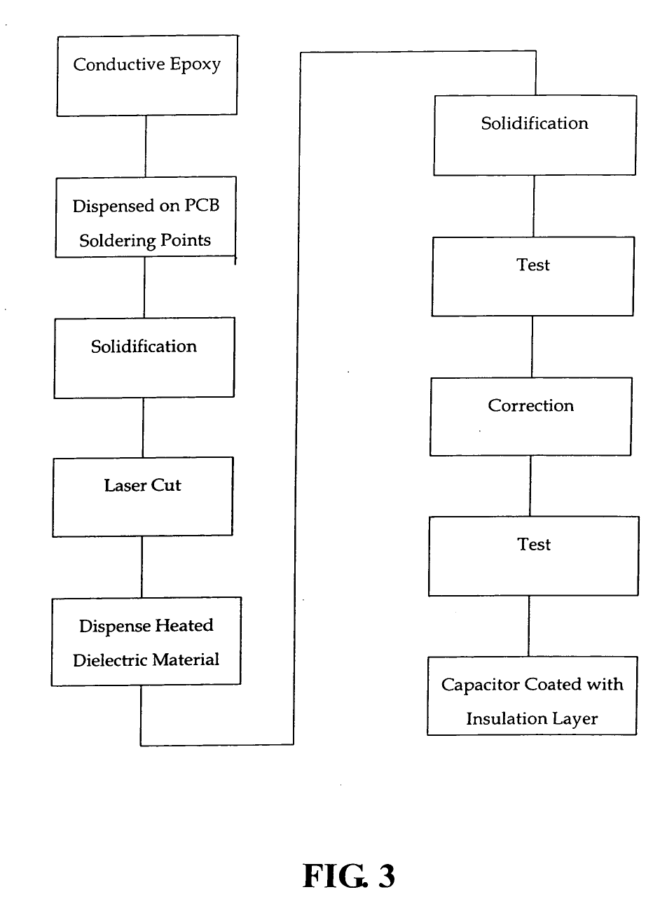

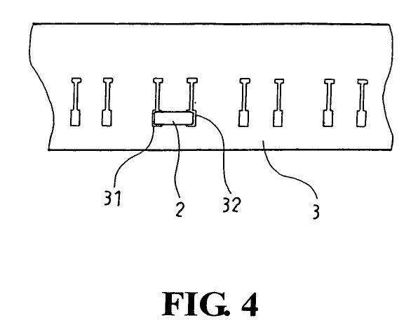

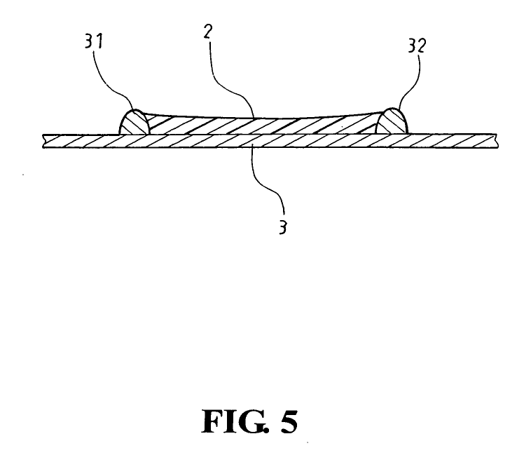

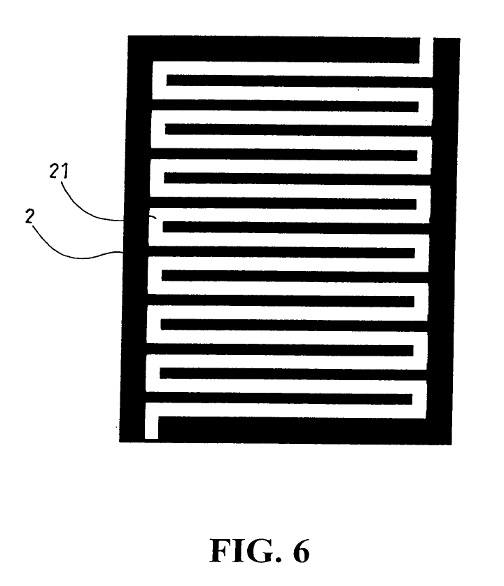

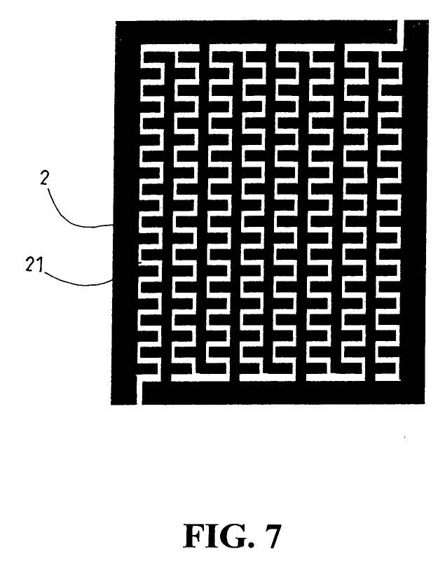

Referring to FIGS. 3 through 7, a dispensable capacitor manufacturing process of the present invention is essentially comprised of the following steps:
A. Dispense a conductive epoxy 2 between two soldering points 31, 32 on a PCB 3 as illustrated in FIGS. 4 and 5.
B. The dispensed conductive epoxy 2 is heated up and solidified.
C. Laser cut on the surface of the solidified conductive epoxy 2 groove 21 in continuous zigzag shaped pattern as illustrated in FIGS. 6 and 7.
D. Coat dielectric material (related to an epoxy with high insulation) on the conductive epoxy 2 after the cut, then solidified. In case of smaller spacing of the groove 21 cut in Step C, the dielectric materials must be heated up and dispensed by permeation, and air bulbs in the dielectric material are removed in a vacuum environment to get more consistent capacity.
E. Run the capacity test, followed with later cut to change the capacity as required before repeating the test.
F. Coat an insulation layer (epoxy) on the dielectric material for protection to improve impact and thermal durability while promoting the binding strength of the PCB (since the binding strength between epoxy and PCB soldering point is comparatively poor).
G. The capacitor on the PCB soldering points is completed.

In addition to the single capacitor provided between two soldering points 31, 32 on the PCB, the capacitor is directly provided on any insulation substrate with sufficient mechanical strength without the soldering process as required in the prior art. Upon the completion of the first layer of conductive epoxy laser cut and coated with the dielectric material, a second layer conductive epoxy may be dispensed to form a double-layer structure for increased capacity and scope of applications.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A dispensable capacitor manufacturing process includes the following steps:
Dispense conductive epoxy between two soldering points on a PCB.
Solidify the conductive epoxy dispensed in Step a.
Laser cut on the solidified conductive epoxy continuous zigzag shaped grooves.
Coat on the conductive epoxy after cut the dielectric material and left solidified.
Run the capacity test, correct, and repeat the test to come up with a finished product of capacitor.
Finally, coat insulation protection layer on the capacitor.

2. The dispensable capacitor manufacturing process of claim 1, wherein the conductive epoxy dispensed between two soldering points on the PCB is heated and solidified.

3. The dispensable capacitor manufacturing process of claim 1, wherein the dielectric material is removed with air bulbs, heated and dispensed in permeation fashion to the conductive epoxy in a vacuum environment in case of smaller spacing between grooves cut on the conductive epoxy.

4. The dispensable capacitor manufacturing process of claim 1, wherein a double-layer dispensable capacitor is made by applying a second layer of the conductive epoxy after the first layer of the conductive epoxy is solidified after the cut and permeated with the heated dielectric material.
